(19) United States
(12) Patent Application Publication
(10) Pub. No.: US 2012/0077427 A1
(43) Pub. Date: Mar. 29, 2012

(54) CONTAINER DATA CENTER AND HEAT DISSIPATION SYSTEM

(75) Inventor: CHAO-KE WEI, Tu-Cheng (TW)

(73) Assignee: HON HAI PRECISION INDUSTRY CO., LTD., Tu-Cheng (TW)

(21) Appl. No.: 12/894,173

(22) Filed: Sep. 30, 2010

(30) Foreign Application Priority Data
Sep. 24, 2010 (TW) 99132282

(51) Int. Cl. H05K 5/02

(52) U.S. Cl. 454/184

(57) ABSTRACT

A container data center includes a movable container, two server systems, an exhaust fan arranged on the container, a cold airflow generating apparatus arranged under the server systems, and a heat shield connected between tops of the server systems. A cold aisle is defined among the server systems, the heat shield, and the cold airflow generating apparatus. A hot aisle is defined among sidewalls of the container, the server systems, the heat shield, and the cold airflow generating apparatus. A bottom of the cold aisle defines an opening to communicate with the cold airflow generating apparatus. The cold airflow generating apparatus includes a blower arranged under the opening, two heat exchangers respectively arranged at opposite sides of the blower, and two air filters respectively arranged around outside of the heat exchangers.

### BACKGROUND

1. Technical Field

The present disclosure relates to data centers, and particularly to a container data center and a heat dissipation system of the container data center.

2. Description of Related Art

With increasing heavy duty use of on-line applications, the need for computer data centers has increased rapidly. Data centers are centralized computing facilities that include many servers, often arranged on server racks or shelves, and one rack or shelf with some servers can be considered a server system. During operation, server systems generate a lot of heat in the data centers, and a common method for dissipating the heat is to use air conditioners, which are very expensive to purchase and operate. Therefore an energy-saving heat dissipation system is needed.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partial, schematic view of an embodiment of a container data center.

FIG. 2 is a cross-sectional, schematic view of the container data center of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

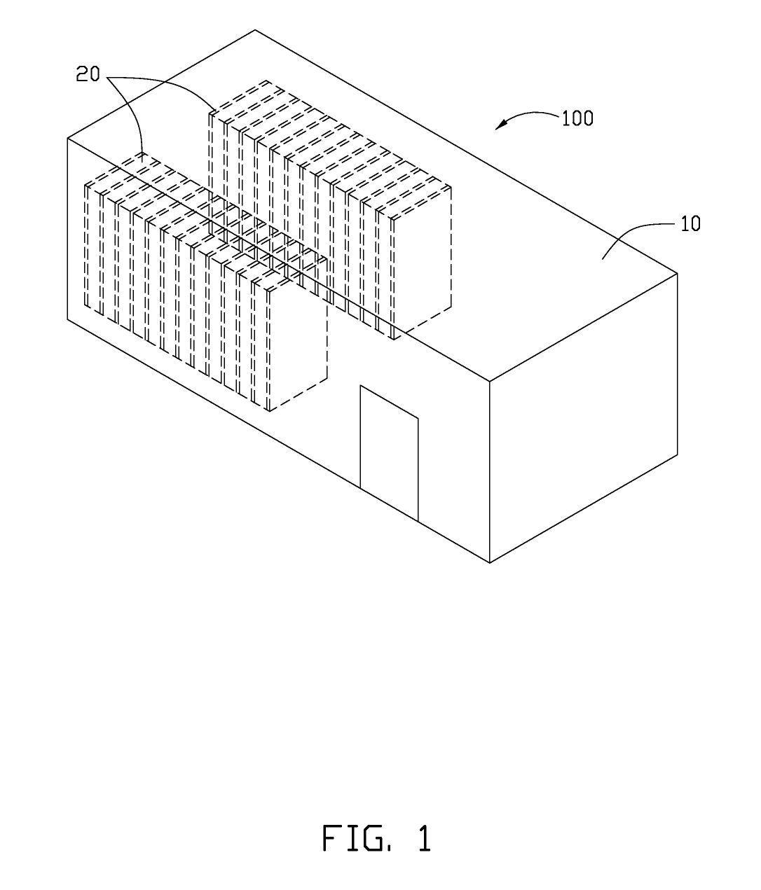

Referring to FIG. 1, an embodiment of a container data center 100 includes a portable container 10 and two server systems 20 installed side by side in the container 10 such that the servers in the systems 20 are in two parallel rows.

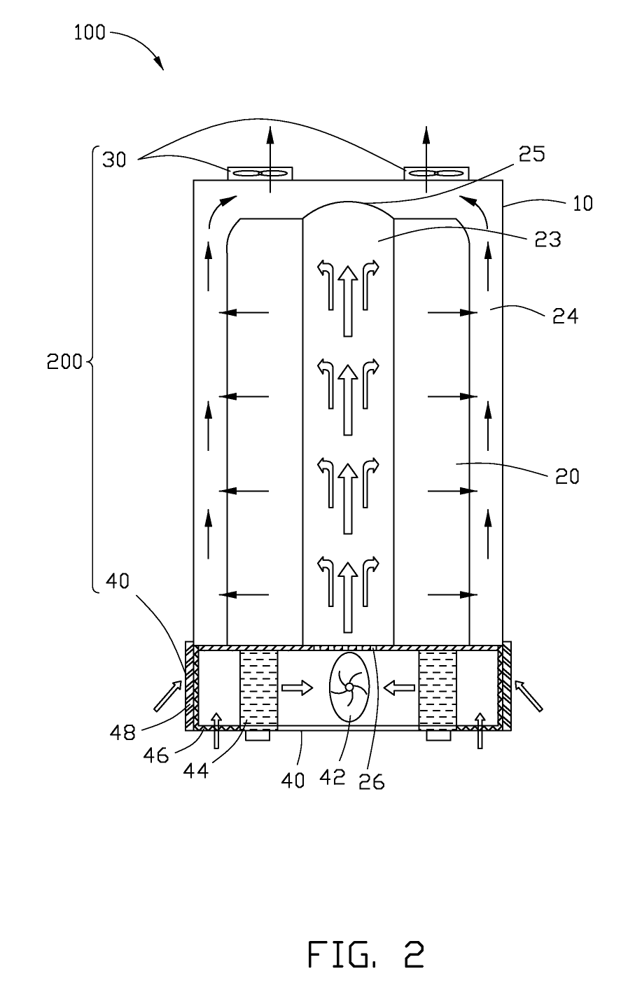

Referring to FIG. 2, the container data center 100 further includes two exhaust fans 30 arranged on the container 10 and a cold airflow generating apparatus 40 arranged under the server systems 20. The exhaust fans 30 communicate with the container 10. A heat shield 25 is provided to connect the tops of the server systems 20. The exhaust fans 30 and the cold airflow generating apparatus 40 form a heat dissipation system 200 in the container data center 100 to dissipate heat for the server systems 20.

In the container data center 100, there are a cold aisle 23 defined among the server systems 20, the heat shield 25, and the cold airflow generating apparatus 40, and a hot aisle 24 defined among sidewalls of the container 10, the server systems 20, the heat shield 25, and the cold airflow generating apparatus 40 (in FIG. 2 the large hollow arrows indicate cold airflow, and the small solid arrows indicate warm or hot airflow). The bottom of the cold aisle 23 (which is also the top of the cold airflow generating apparatus 40) defines a number of openings 26 used to communicate the cold aisle 23 with the cold airflow generating apparatus 40.

The cold airflow generating apparatus 40 includes a blower 42 arranged under the openings 26, two heat exchangers 44 respectively arranged at opposite sides of the blower 44, and two air filters 46 respectively arranged around the outside of the heat exchangers 44 to prevent dust entering the heat exchangers 44. In one embodiment, two rain shields 48, such as louvered windows, are mounted on the air filters 46 to prevent water entering the air filters 46.

In use, the blower 42 sucks air through the air filters 46 into the heat exchangers 44. The heat exchangers 44 cool the air, and then the cold airflow is blown into the cold aisle 23 by the blower 42 to cool the server systems 20. The server systems 20 generate heat into the hot aisle 24, and hot airflow in the hot aisle 24 is exhausted by the exhaust fans 30 to outside of the container 10. When the ambient temperature of the container 10 is low enough, the heat exchangers 44 may be shut down to save electricity. The container data center 100 uses the heat dissipation system 200 to dissipate heat, which consumes less power than common air conditioners.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A container data center comprising:
a portable container;
two server systems installed in the container in two parallel rows;
an exhaust fan arranged on the container and communicating with the container;
a cold airflow generating apparatus arranged under the server systems; and
a heat shield connected between tops of the server systems, wherein a cold aisle is defined among the server systems, the heat shield, and the cold airflow generating apparatus, a hot aisle is defined among sidewalls of the container, the server systems, the heat shield, and the cold airflow generating apparatus, a bottom of the cold aisle defines an opening to communicate with the cold airflow generating apparatus;
wherein the cold airflow generating apparatus comprises:
a blower arranged under the opening;
two heat exchangers respectively arranged at opposite sides of the blower; and
two air filters respectively arranged around outside of the heat exchangers.

2. The container data center of claim 1, wherein the cold airflow generating apparatus further comprises two rain shields mounted on the air filters, respectively.

3. A heat dissipation system used to dissipate heat for a server system assembly comprising two server systems arranged in two parallel rows, a cold aisle is defined between the server systems, a hot aisle is defined among sidewalls of the server system assembly and the server systems, the heat dissipation system comprising:
an exhaust fan arranged on the server systems to exhaust heat airflow in the hot aisle to outside of the server system assembly; and
a cold airflow generating apparatus arranged under the server systems to provide cold airflow to the cold aisle, the cold airflow generating apparatus comprising:
a blower arranged under the cold airflow and communicating with the cold airflow;
two heat exchangers respectively arranged at opposite sides of the blower; and
two air filters respectively arranged around outside of the heat exchangers.

4. The heat dissipation system of claim 3, further comprising two rain shields mounted on the air filters.
